(19) United States
(12) Patent Application Publication
(10) Pub. No.: US 2023/0180562 A1
(43) Pub. Date: Jun. 8, 2023

(54) DISPLAY DEVICE

(71) Applicant: WUHAN CHINA STAR OPTOELECTRONICS SEMICONDUCTOR DISPLAY TECHNOLOGY CO., LTD., Wuhan (CN)

(72) Inventor: Caihua DING, Wuhan (CN)

(73) Assignee: WUHAN CHINA STAR OPTOELECTRONICS SEMICONDUCTOR DISPLAY TECHNOLOGY CO., LTD., Wuhan (CN)

(21) Appl. No.: 16/966,026

(22) PCT Filed: Mar. 17, 2020
(86) PCT No.: PCT/CN2020/079597

§ 371 Date: Jul. 30, 2020

(30) Foreign Application Priority Data
Nov. 25, 2019 (CN) 201911167878.3

(51) Int. Cl. H10K 59/179

(52) U.S. Cl. CPC H10K 59/179

(57) ABSTRACT

A display device includes a display panel and an integrated circuit chip. The integrated circuit chip is provided with a plurality of first binding terminals arranged at intervals, and conductive particles are in contact between the first binding terminals and second binding terminals of the display panel. A groove is provided on opposite sides of two adjacent first binding terminals, and the groove is filled with a first insulating layer.

### FIELD OF INVENTION

The present disclosure relates to the field of display technologies, and more particularly to a display device.

### BACKGROUND OF INVENTION

At present, Chip on PI (COP) binding technology has become one of high-end bonding technologies commonly developed in the display panel industry. An advantage of COP binding is that it can better reduce costs. In addition, the development of organic light emitting diode (OLED) technology makes it possible to bend the display screen. The display screen with ultra-narrow border is more attractive to consumers. COP binding technology directly binds an integrated circuit chip (IC) to a terminal area of a display panel, which can further reduce a distance of the border.

The COP binding technology is to form a plurality of spaced bump terminals on the IC, and then bind the bump terminals to the display panel through anisotropic conductive film (ACF) to realize electrical signal conduction. Under a combined effect of temperature, pressure, and time, conductive particles in a ACF conductive adhesive realize conduction between the IC and the display panel in a vertical direction and a horizontal insulation.

However, during a COP binding process, a resin material in the ACF conductive adhesive melts at high temperature and becomes fluid. When the conductive particles in the ACF conductive adhesive are pressed, an adhesive material flows into space between the protruding terminals, thereby easily causing the adjacent protruding terminals to conduct laterally and causing a short circuit.

### Technical Problem

During a COP binding process, when the conductive particles in the ACF conductive adhesive are pressed, an adhesive material flows into space between the protruding terminals, thereby easily causing the adjacent protruding terminals to conduct laterally and causing a short circuit. The present invention can solve the above issues.

### SUMMARY OF INVENTION

An embodiment of the present invention provides a display device comprising a display panel and an integrated circuit chip. The integrated circuit chip is provided with a plurality of first binding terminals arranged at intervals, and conductive particles are in contact between the first binding terminals and second binding terminals of the display panel. A groove is provided on opposite sides of two adjacent first binding terminals, and the groove is filled with a first insulating layer. A depth of the groove is less than or equal to one eighth of a width of each of the first binding terminals, and a width of the groove is greater than or equal to half a thickness of each of the first binding terminals.

In some embodiments, the width of the groove is less than or equal to four fifths of the thickness of each of the first binding terminals.

In some embodiments, the groove penetrates front and rear sides of each of the first binding terminals.

In some embodiments, a thickness of the first insulating layer is less than or equal to the depth of the groove.

In some embodiments, an entire cross section of each of the first binding terminals is in a shape of “[” or “]”.

In some embodiments, the groove is provided around a peripheral side of each of the first binding terminals.

In some embodiments, an entire cross section of each of the first binding terminals is in an “I” shape.

In some embodiments, the display panel comprises a substrate, an array substrate disposed on the substrate, a light emitting layer, a touch layer, and a package cover plate stacked on the array substrate. The array substrate has a display area and a binding area, and the second binding terminals are positioned in the binding area.

An embodiment of the present invention further provides a display device comprising a display panel and an integrated circuit chip. The integrated circuit chip is provided with a plurality of first binding terminals arranged at intervals, and conductive particles are in contact between the first binding terminals and second binding terminals of the display panel. A groove is provided on opposite sides of two adjacent first binding terminals, and the groove is filled with a first insulating layer.

In some embodiments, a depth of the groove is less than or equal to one eighth of a width of each of the first binding terminals.

In some embodiments, a width of the groove is greater than or equal to half a thickness of each of the first binding terminals.

In some embodiments, the width of the groove is less than or equal to four fifths of the thickness of each of the first binding terminals.

In some embodiments, the groove penetrates front and rear sides of each of the first binding terminals.

In some embodiments, a thickness of the first insulating layer is less than or equal to the depth of the groove.

In some embodiments, an entire cross section of each of the first binding terminals is in a shape of “[” or “]”.

In some embodiments, the groove is provided around a peripheral side of each of the first binding terminals.

In some embodiments, an entire cross section of each of the first binding terminals is in an “I” shape.

In some embodiments, the display panel comprises a substrate, an array substrate disposed on the substrate, a light emitting layer, a touch layer, and a package cover plate stacked on the array substrate. The array substrate has a display area and a binding area, and the second binding terminals are positioned in the binding area.

### Beneficial Effect

By providing the first insulating layer on a first side of the binding terminal, insulating effect of the first insulating layer is used to prevent a large amount of conductive particles from accumulating in space between the first binding terminals, thereby avoid causing lateral conduction of the adjacent first binding terminals and avoid causing short circuit. This can save material costs while ensuring that a vertical binding area of the first binding terminal and the second binding terminal is unchanged. In addition, by providing the groove on the first side of the first binding terminal and filling the groove with the first insulating layer, strength of a hollowed-out area of the first binding terminal can be supplemented.

### DESCRIPTION OF DRAWINGS

In order to explain the technical solution in the embodiments or the prior art more clearly, the accompanying drawings used in the description of the embodiments or the prior art will be briefly introduced below. Obviously, the drawings in the following description are only some embodiments of the present invention. For those of ordinary skill in the art, other drawings can be obtained according to the drawings without paying creative efforts.

FIG. 1 is a schematic structural diagram of a display device according to an embodiment of the present invention.

FIG. 2 is a schematic structural diagram of a groove according to an embodiment of the present invention.

FIG. 3 is a schematic structural diagram of a display device according to another embodiment of the present invention.

FIG. 4 and FIG. 5 are schematic diagrams of steps of forming a first insulating layer and a second insulating layer according to an embodiment of the present invention.

FIG. 6 is a schematic plan view of an array substrate according to an embodiment of the present invention.

FIG. 7 is a schematic structural diagram of a display panel according to an embodiment of the invention.

### REFERENCE MARK

10, integrated circuit chip; 11, first binding terminal; 12, first insulating layer; 14, groove; 16, first side; 20, display panel; 21, second binding terminal; 22, substrate; 23, array substrate; 231, display area; 232, binding area; 233, bending area; 24, light emitting layer; 25, optical adhesive layer; 26, touch layer; 27, package layer; 30, conductive adhesive layer; 31. conductive particles.

### DETAILED DESCRIPTION OF PREFERRED EMBODIMENTS

The technical solutions in the embodiments of the present application will be described clearly and completely with reference to the drawings in the embodiments of the present application. Obviously, the described embodiments are only a part of the embodiments of the present application, but not all the embodiments. Based on the embodiments in the present application, all other embodiments obtained by those skilled in the art without making creative efforts fall within the protection scope of the present application.

In a current display device, during a COP binding process, when conductive particles in an ACF conductive adhesive are pressed, an adhesive material flows into space between protruding terminals, thereby easily causing adjacent protruding terminals to conduct laterally and causing a short circuit. The present invention can solve the above issues.

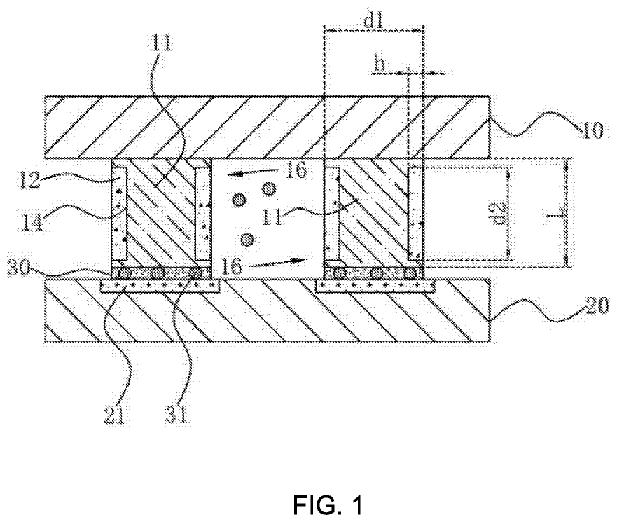

A display device is provided, as shown in FIG. 1. The display device includes a display panel 20 and an integrated circuit chip 10. The integrated circuit chip 10 is provided with a plurality of first binding terminals 11 arranged at intervals. The display panel 20 is provided with second binding terminals 21 corresponding one-to-one with the first binding terminals 11.

It should be noted that the display panel 20 may be a flexible display panel 20, or a flexible organic light emitting display panel 20.

It should be noted that the first binding terminals 11 may be arranged side by side along a length direction of the integrated circuit chip 10, and the first binding terminals 11 may also be arranged in an array.

Specifically, conductive particles 31 are provided between the first binding terminal 11 and the second binding terminal 21 of the display panel 20. The conductive particles 31 are in contact with the first binding terminal 11 and the second binding terminal 21, so that the integrated circuit chip 10 and the display panel 20 are electrically connected in a vertical direction and insulated in a horizontal direction.

It should be noted that when the integrated circuit chip 10 is bound to the display panel 20, a conductive adhesive layer 30 with conductive particles 31 is formed on the second binding terminal 21 first. The first binding terminal 11 and the second binding terminal 21 are aligned. The integrated circuit chip 10 and the display panel 20 are pressed at a high temperature. The conductive particles 31 are in contact with the first binding terminal 11 and the second binding terminal 21 to realize electrical connection between the integrated circuit chip 10 and the display panel 20.

A groove 14 is provided on opposite sides of two adjacent first binding terminals 11, and the groove 14 is filled with a first insulating layer 12.

As shown in FIG. 1, the opposite sides of the two adjacent first binding terminals 11 are the first side 16, the groove 14 is provided on the first side 16, and the first insulating layer 12 is filled in the groove 14.

By providing the first insulating layer 12 on the first side 16 of the first binding terminal 11, even if the conductive particles 31 flow into the space between the adjacent first binding terminals 11 with the conductive adhesive, insulating property of the first insulating layer 12 isolates the conductive particles 31 from the first binding terminals 11, thereby preventing the conductive particles 31 from gathering, thereby avoid causing lateral conduction of the adjacent first binding terminals 11 and avoid causing short circuit.

It should be noted that the conductive particles 31 are generally a multilayer spherical structure. A diameter of the conductive particles 31 can be selected from 3 to 6 microns according to needs of different products. The conductive particles 31 may be formed by plating a high-hardness metal on an outer layer of a high molecular polymer. The high molecular polymer may be polystyrene. The high-hardness metal may be cobalt or nickel.

It should be noted that those skilled in the art know that the higher the resolution of the display panel 20, the higher the requirements on the capability of the integrated circuit chip 10 to operate and store data. As a result, a number of second binding terminals 21 bound to the integrated circuit chip 10 on the display panel 20 will increase. When an overall area of the integrated circuit chip 10 is unchanged, the spacing between the first binding terminals 11 will become smaller and smaller. With the insulating effect of the first insulating layer 12, it is not necessary to reduce the diameter of the conductive particles 31 to prevent the conductive particles 31 from aggregating thereby avoid causing lateral conduction of the adjacent first binding terminals 11 and avoid causing short circuit. This reduces process difficulty, increases a selection range of the diameter of the conductive particles 31 in the binding process, and saves the purchase cost.

It should be noted that a preparation material of the first binding terminal 11 is generally a metal with higher cost, such as gold and copper. By forming the groove 14 on the first side 16 of the first binding terminal 11, it is possible to ensure that a vertical binding area and strength of the first binding terminal 11 and the second binding terminal 21 are unchanged, that is, it does not affect In the case of vertical conduction, material cost is saved. The first insulating layer 12 is filled in the groove 14, on the one hand, the insulating ability of the first insulating layer 12 can be used, on the other hand, the strength of the hollowed-out area of the first binding terminal 11 can be supplemented by the first insulating layer 12.

Specifically, a depth h of the groove 14 is less than or equal to one eighth of a width d1 of the first binding terminal 11.

Further, a width d2 of the groove 14 is greater than or equal to half a thickness L of the first binding terminal 11. The width d2 of the groove 14 is less than or equal to four fifths of the thickness L of the first binding terminal 11.

By designing the depth h and width L of the groove 14, while saving material costs, the strength of the first binding terminal 11 and the insulation effect of the first insulating layer 12 are ensured.

It should be noted that, referring to FIG. 1, the width d1 of the first binding terminal 11 is a distance between left and right sides of the first binding terminal 11 along a first direction. The width d2 of the groove 14 is a distance between upper and lower side walls of the groove 14 along a second direction. The thickness L of the first binding terminal 11 is a distance between upper and lower sides of the first binding terminal 11 along the second direction.

Specifically, the thickness of the first insulating layer 12 is less than or equal to the depth of the groove 14, thereby preventing the first insulating layer 12 from causing a decrease in the space between the first binding terminals 11.

It should be noted that material for preparing the first insulating layer 12 includes, but is not limited to, silicon nitride, silicon oxide, polyimide, or acrylic.

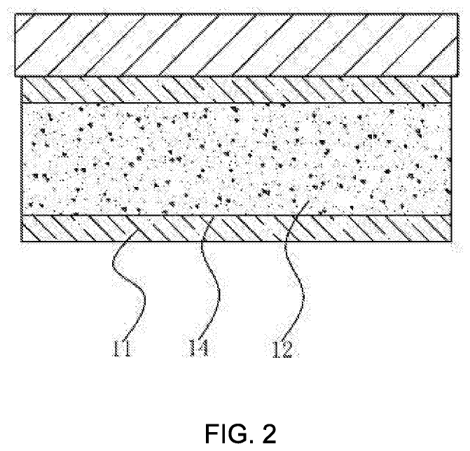

As shown in FIG. 2, in one embodiment, the groove 14 penetrates front and rear sides of the first binding terminal 11.

In an embodiment, the groove 14 is disposed around peripheral side of the first binding terminal 11, that is, the groove 14 is provided on all four sides of the first binding terminal 11.

Further, an entire cross section of the first binding terminal is in an “I” shape (see FIG. 1).

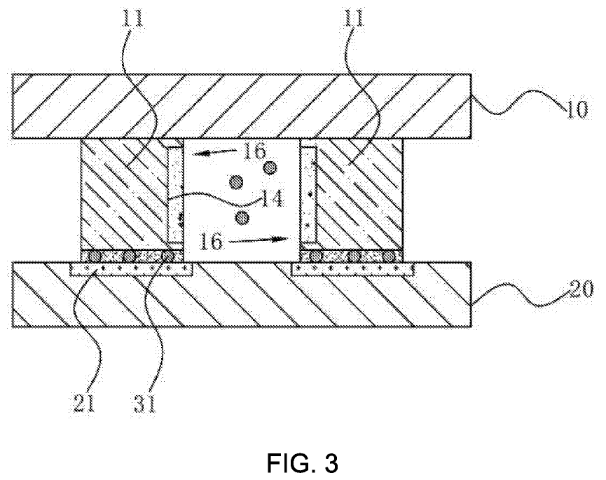

In another embodiment, as shown in FIG. 3, the groove 14 is formed only on one side or both sides or three sides of the first binding terminal 11, and an entire cross section of the first binding terminal 11 is in a shape of “[” or “]”.

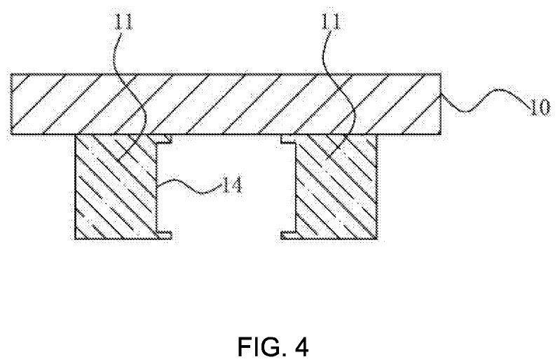

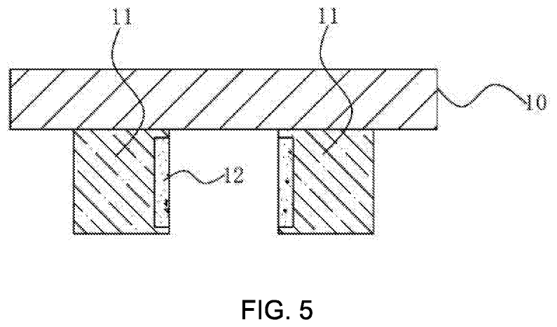

As shown in FIG. 4 and FIG. 5, FIG. 4 and FIG. 5 are schematic diagrams of the steps of forming the first insulating layer 12.

As shown in FIG. 4, the groove 14 is formed on the first side 16 of the first insulating layer 12.

As shown in FIG. 5, the first insulating layer 12 filling the groove 14 is formed in the groove 14 using a film forming or coating process.

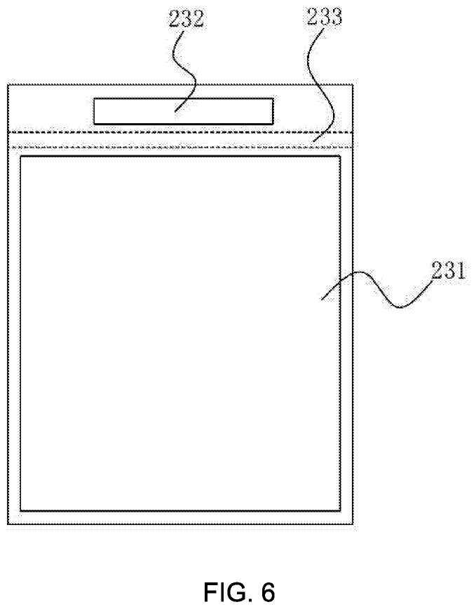

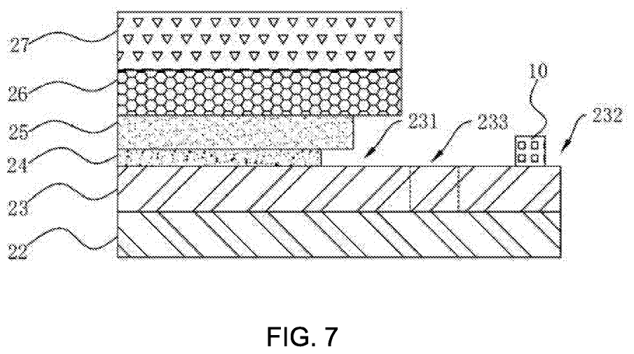

As shown in FIG. 6 and FIG. 7, the display panel 20 includes a substrate 22, an array substrate 23 disposed on the substrate 22, a light emitting layer 24, a touch layer 26, and a package layer 27 stacked on the array substrate 23.

The array substrate 23 has a display area 231 and a binding area 232, and the second binding terminal 21 is positioned in the binding area 232.

The substrate 22 is a flexible substrate 22. The array substrate 23 is a flexible array substrate 23. A bending area 233 is also provided between the display area 231 and the binding area 232. In this way, after the integrated circuit chip 10 is bound to the binding area 232, the integrated circuit chip 10 is bent to a back side of the substrate 22, and a border width of the display panel 20 is reduced.

The touch layer 26 may be bonded to the light emitting layer 24 through an optical adhesive layer 25, and the package layer 27 may be an package cover plate.

Beneficial effect of embodiments of the present invention: By providing the first insulating layer 12 on a first side 16 of the binding terminal 11, insulating effect of the first insulating layer 12 is used to prevent a large amount of conductive particles 15 from accumulating in space between the first binding terminals 11, thereby avoid causing lateral conduction of the adjacent first binding terminals 11 and avoid causing short circuit. This can save material costs while ensuring that a vertical binding area of the first binding terminal 11 and the second binding terminal 12 is unchanged. In addition, by providing the groove 14 on the first side 16 of the first binding terminal 11 and filling the groove 14 with the first insulating layer 12, strength of a hollowed-out area of the first binding terminal 11 can be supplemented.

In the above embodiments, the description of each embodiment has its own emphasis. For a part that is not detailed in an embodiment, you can refer to the related descriptions of other embodiments.

This article uses specific examples to explain the principles and implementation of the present application. The descriptions of the above embodiments are only used to help understand the technical solutions and core ideas of the present application. Those of ordinary skill in the art should understand that they can still modify the technical solutions described in the foregoing embodiments, or equivalently replace some of the technical features. However, these modifications or substitutions do not deviate from the scope of the technical solutions of the embodiments of the present application.

What is claimed is:

1. A display device, comprising:
a display panel; and
an integrated circuit chip, wherein the integrated circuit chip is provided with a plurality of first binding terminals arranged at intervals, and conductive particles are in contact between the first binding terminals and second binding terminals of the display panel; and
wherein a groove is provided on opposite sides of two adjacent first binding terminals, and the groove is filled with a first insulating layer; a depth of the groove is less than or equal to one eighth of a width of each of the first binding terminals, and a width of the groove is greater than or equal to half a thickness of each of the first binding terminals.

2. The display device according to claim 1, wherein the width of the groove is less than or equal to four fifths of the thickness of each of the first binding terminals.

3. The display device according to claim 1, wherein the groove penetrates front and rear sides of each of the first binding terminals.

4. The display device according to claim 1, wherein a thickness of the first insulating layer is less than or equal to the depth of the groove.

5. The display device according to claim 1, wherein an entire cross section of each of the first binding terminals is in a shape of “[” or “]”.

6. The display device according to claim 1, wherein the groove is provided around a peripheral side of each of the first binding terminals.

7. The display device according to claim 6, an entire cross section of each of the first binding terminals is in an “I” shape.

8. The display device according to claim 1, wherein the display panel comprises:
a substrate;
an array substrate disposed on the substrate;
a light emitting layer, a touch layer, and a package cover plate stacked on the array substrate;
wherein the array substrate has a display area and a binding area, and the second binding terminals are positioned in the binding area.

9. A display device, comprising:
a display panel; and
an integrated circuit chip, wherein the integrated circuit chip is provided with a plurality of first binding terminals arranged at intervals, and conductive particles are in contact between the first binding terminals and second binding terminals of the display panel; and
wherein a groove is provided on opposite sides of two adjacent first binding terminals, and the groove is filled with a first insulating layer.

10. The display device according to claim 9, wherein a depth of the groove is less than or equal to one eighth of a width of each of the first binding terminals.

11. The display device according to claim 9, wherein a width of the groove is greater than or equal to half a thickness of each of the first binding terminals.

12. The display device according to claim 11, wherein the width of the groove is less than or equal to four fifths of the thickness of each of the first binding terminals.

13. The display device according to claim 9, wherein the groove penetrates front and rear sides of each of the first binding terminals.

14. The display device according to claim 9, wherein a thickness of the first insulating layer is less than or equal to a depth of the groove.

15. The display device according to claim 9, wherein an entire cross section of each of the first binding terminals is in a shape of “[” or “]”.

16. The display device according to claim 9, wherein the groove is provided around a peripheral side of each of the first binding terminals.

17. The display device according to claim 16, an entire cross section of each of the first binding terminals is in an “I” shape.

18. The display device according to claim 9, wherein the display panel comprises:
a substrate;
an array substrate disposed on the substrate;
a light emitting layer, a touch layer, and a package cover plate stacked on the array substrate;
wherein the array substrate has a display area and a binding area, and the second binding terminals are positioned in the binding area.
